(19) United States
(12) Patent Application Publication
(10) Pub. No.: US 2026/0013178 A1
(43) Pub. Date: Jan. 8, 2026

(54) INDEPENDENT GATE CONTACT CONNECTION FOR STACKED TRANSISTORS

(71) Applicant: International Business Machines Corporation, Armonk, NY (US)

(72) Inventors: Juntao Li, Cohoes, NY (US); Lijuan Zou, Albany, NY (US); Ruilong Xie, Niskayuna, NY (US); Tao Li, Slingerlands, NY (US)

(21) Appl. No.: 18/761,391

(22) Filed: Jul. 2, 2024

(51) Int. Cl. H01L 29/423; H01L 21/822; H01L 21/8238; H01L 27/06; H01L 27/092; H01L 29/06; H01L 29/66; H01L 29/775; H01L 29/786

(52) U.S. Cl. CPC H10D 30/6735; H10D 30/014; H10D 30/43; H10D 30/6757; H10D 62/121; H10D 84/0177; H10D 84/0188; H10D 84/038; H10D 84/856; H10D 88/00; H10D 88/01

(57) ABSTRACT

Embodiments of the invention include a semiconductor structure having first stacked transistors including a first upper transistor over a first lower transistor. Second stacked transistors are adjacent to the first stacked transistors. A gate structure includes a gate extension into a shallow trench isolation region, where a non-conductive frontside gate cut through the gate structure isolates the first stacked transistors and the second stacked transistors, where a contact through the non-conductive frontside gate cut contacts the gate extension and is coupled to the first lower transistor.

### BACKGROUND

The present invention generally relates to fabrication methods and resulting structures for integrated circuits (ICs), and more specifically, to fabrication methods and resulting structures configured and arranged to provide an independent gate contact connection for stacked transistors.

ICs (also referred to as a chip or a microchip) include electronic circuits on a wafer. The wafer is a semiconductor material, such as, for example, silicon or other materials. An IC is formed of a large number of devices, such as transistors, capacitors, resistors, etc., which are formed in layers of the IC and interconnected with wiring in the back-end-of-line (BEOL) layers of the wafer. Typical ICs are formed by first fabricating individual semiconductor devices using processes referred to generally as the front-end-of-line (FEOL). A metal-oxide-semiconductor field-effect transistor (MOSFET) is a transistor used for amplifying or switching electronic signals. The MOSFET has a source, a drain, and a metal oxide gate electrode. A conventional FET is a planar device where the entire channel region of the device is formed parallel and slightly below the planar upper surface of the semiconducting substrate. In contrast to a planar FET, there are so-called three-dimensional (3D) devices, such as a FinFET device, which is a three-dimensional structure. One type of device that shows promise for advanced integrated circuit products is generally known as a nanosheet transistor. In general, a nanosheet transistor has a fin-type channel structure that includes a plurality of vertically spaced-apart sheets of semiconductor material. A gate structure for the device is positioned around each of these spaced-apart layers of channel semiconductor material.

### SUMMARY

Embodiments of the present invention are directed to providing independent gate contact connection for stacked transistors. A semiconductor structure includes first stacked transistors having a first upper transistor over a first lower transistor and second stacked transistors adjacent to the first stacked transistors. A gate structure includes a gate extension into a shallow trench isolation region, where a non-conductive frontside gate cut through the gate structure isolates the first stacked transistors and the second stacked transistors, where a contact through the non-conductive frontside gate cut contacts the gate extension and is coupled to the first lower transistor. As technical effects and technical solutions, the present disclosure provides independent gate contact to a lower gate of the lower transistor in the stacked transistors, thereby providing independent gate control for upper and lower transistors in the stacked transistors. Advantageously, the present disclosure isolates the upper and lower gates of the upper and lower transistors in the stacked transistors from neighboring stacked transistors.

According to one or more embodiments, a method is provided. The method includes providing first stacked transistors having a first upper transistor over a first lower transistor. The method includes providing second stacked transistors adjacent to the first stacked transistors, a gate structure comprising a gate extension into a shallow trench isolation region, where a non-conductive frontside gate cut through the gate structure isolates the first stacked transistors and the second stacked transistors, where a contact through the non-conductive frontside gate cut contacts the gate extension and is coupled to the first lower transistor.

Other embodiments of the present invention implement features of the above-described devices/structures in methods and/or implement features of the methods in devices/structures.

Additional technical features and benefits are realized through the techniques of the present invention. Embodiments and aspects of the invention are described in detail herein and are considered a part of the claimed subject matter. For a better understanding, refer to the detailed description and to the drawings.

### BRIEF DESCRIPTION OF THE DRAWINGS

The specifics of the exclusive rights described herein are particularly pointed out and distinctly claimed in the claims at the conclusion of the specification. The foregoing and other features and advantages of the embodiments of the invention are apparent from the following detailed description taken in conjunction with the accompanying drawings in which:

FIGS. 1A, 1B, 1C, and 1D respectively depict a top view and cross-sectional views of a portion of an integrated circuit (IC) under-fabrication after fabrication operations according to one or more embodiments of the invention;

FIGS. 2A, 2B, 2C, and 2D depict a top view and cross-sectional views of a portion of an IC under-fabrication after fabrication operations according to one or more embodiments of the invention;

FIGS. 3A, 3B, 3C, and 3D depict a top view and cross-sectional views of a portion of an IC under-fabrication after fabrication operations according to one or more embodiments of the invention;

FIGS. 4A, 4B, 4C, and 4D depict a top view and cross-sectional views of a portion of an IC under-fabrication after fabrication operations according to one or more embodiments of the invention;

FIGS. 5A, 5B, 5C, and 5D depict a top view and cross-sectional views of a portion of an IC under-fabrication after fabrication operations according to one or more embodiments of the invention;

FIGS. 6A, 6B, 6C, and 6D depict a top view and cross-sectional views of a portion of an IC under-fabrication after fabrication operations according to one or more embodiments of the invention;

FIGS. 7A, 7B, 7C, and 7D depict a top view and cross-sectional views of a portion of an IC under-fabrication after fabrication operations according to one or more embodiments of the invention;

FIGS. 8A, 8B, 8C, and 8D depict a top view and cross-sectional views of a portion of an IC under-fabrication after fabrication operations according to one or more embodiments of the invention;

FIGS. 9A, 9B, 9C, and 9D depict a top view and cross-sectional views of a portion of an IC under-fabrication after fabrication operations according to one or more embodiments of the invention;

FIGS. 10A, 10B, 10C, and 10D depict a top view and cross-sectional views of a portion of an IC under-fabrication after fabrication operations according to one or more embodiments of the invention;

FIGS. 11A, 11B, 11C, and 11D depict a top view and cross-sectional views of a portion of an IC under-fabrication after fabrication operations according to one or more embodiments of the invention;

FIGS. 12A, 12B, 12C, and 12D depict a top view and cross-sectional views of a portion of an IC under-fabrication after fabrication operations according to one or more embodiments of the invention; and

FIG. 13 depicts a flowchart of a method of forming a semiconductor device according to one or more embodiments of the invention.

### DETAILED DESCRIPTION

Embodiments of the present disclosure are directed to a semiconductor structure. The semiconductor structure includes first stacked transistors having a first upper transistor over a first lower transistor and second stacked transistors adjacent to the first stacked transistors. A gate structure includes a gate extension into a shallow trench isolation region, where a non-conductive frontside gate cut through the gate structure isolates the first stacked transistors and the second stacked transistors, where a contact through the non-conductive frontside gate cut contacts the gate extension and is coupled to the first lower transistor. As technical effects and technical solutions, the present disclosure provides independent gate contact to a lower gate of the lower transistor in the stacked transistors, thereby providing independent gate control for upper and lower transistors in the stacked transistors. Advantageously, the present disclosure isolates the upper and lower gates of the upper and lower transistors in the stacked transistors from neighboring stacked transistors.

In addition to one or more of the features described above or below, or as an alternative, further embodiments disclose the non-conductive frontside gate cut isolates the gate structure into an upper gate structure and a lower gate structure, the lower gate structure including the gate extension. Technical effects and technical solutions include separating the gate structure of the stacked transistors into upper and lower gates for individual gate control.

In addition to one or more of the features described above or below, or as an alternative, further embodiments disclose the first upper transistor includes an upper gate structure and the first lower transistor comprises a lower gate structure, the upper and lower gate structures being formed by the non-conductive frontside gate cut. Technical effects and technical solutions include separating the gate structure of the stacked transistors into upper and lower gates for individual gate control.

In addition to one or more of the features described above or below, or as an alternative, further embodiments disclose the first stacked transistors include a middle dielectric isolation layer separating the first upper transistor from the first lower transistor. Technical effects and technical solutions include support for providing individual gate control for upper and lower transistors in the stacked transistors.

In addition to one or more of the features described above or below, or as an alternative, further embodiments disclose a non-conductive backside gate cut is in contact with the middle dielectric isolation layer, thereby forming a lower gate structure of the first lower transistor. Technical effects and technical solutions include using the non-conductive backside gate cut to provide individual gate control for upper and lower transistors in the stacked transistors.

In addition to one or more of the features described above or below, or as an alternative, further embodiments disclose a shallow non-conductive frontside gate cut is in contact with both the middle dielectric isolation layer and the non-conductive frontside gate cut. Technical effects and technical solutions include using the shallow non-conductive frontside gate cut to provide individual gate control for upper and lower transistors in the stacked transistors.

In addition to one or more of the features described above or below, or as an alternative, further embodiments disclose a via is connected to the contact in order to couple the gate extension to a frontside interconnect. Technical effects and technical solutions include providing frontside access and control to the lower gate structure of the lower transistor in the stacked transistors.

In addition to one or more of the features described above or below, or as an alternative, further embodiments disclose a cavity in the shallow trench isolation region is filled with the gate extension. Technical effects and technical solutions provide the gate extension that is utilized to provide individual gate control for the lower transistor in the stacked transistors.

In addition to one or more of the features described above or below, or as an alternative, further embodiments disclose the first stacked transistors include a bottom dielectric isolation layer such that the gate extension extends below the bottom dielectric isolation layer. Technical effects and technical solutions provide the gate extension that is utilized to provide individual gate control for the lower transistor in the stacked transistors.

Embodiments of the present disclosure are directed to a method of forming a semiconductor structure. The method includes providing first stacked transistors having a first upper transistor over a first lower transistor. The method includes providing second stacked transistors adjacent to the first stacked transistors, a gate structure comprising a gate extension into a shallow trench isolation region, where a non-conductive frontside gate cut through the gate structure isolates the first stacked transistors and the second stacked transistors, where a contact through the non-conductive frontside gate cut contacts the gate extension and is coupled to the first lower transistor. As technical effects and technical solutions, the present disclosure provides independent gate contact to a lower gate of the lower transistor in the stacked transistors, thereby providing independent gate control for upper and lower transistors in the stacked transistors. Advantageously, the present disclosure isolates the upper and lower gates of the upper and lower transistors in the stacked transistors from neighboring stacked transistors.

In addition to one or more of the features described above or below, or as an alternative, further embodiments disclose the non-conductive frontside gate cut isolates the gate structure into an upper gate structure and a lower gate structure, the lower gate structure including the gate extension. Technical effects and technical solutions include separating the gate structure of the stacked transistors into upper and lower gates for individual gate control.

In addition to one or more of the features described above or below, or as an alternative, further embodiments disclose the first upper transistor includes an upper gate structure and the first lower transistor comprises a lower gate structure, the upper and lower gate structures being formed by the non-conductive frontside gate cut. Technical effects and technical solutions include separating the gate structure of the stacked transistors into upper and lower gates for individual gate control.

In addition to one or more of the features described above or below, or as an alternative, further embodiments disclose the first stacked transistors comprise a middle dielectric isolation layer separating the first upper transistor from the first lower transistor. Technical effects and technical solutions include support for providing individual gate control for upper and lower transistors in the stacked transistors.

In addition to one or more of the features described above or below, or as an alternative, further embodiments disclose a non-conductive backside gate cut is in contact with the middle dielectric isolation layer, thereby forming a lower gate structure of the first lower transistor. Technical effects and technical solutions include using the non-conductive backside gate cut to provide individual gate control for upper and lower transistors in the stacked transistors.

In addition to one or more of the features described above or below, or as an alternative, further embodiments disclose a shallow non-conductive frontside gate cut is in contact with both the middle dielectric isolation layer and the non-conductive frontside gate cut. Technical effects and technical solutions include using the shallow non-conductive frontside gate cut to provide individual gate control for upper and lower transistors in the stacked transistors.

In addition to one or more of the features described above or below, or as an alternative, further embodiments disclose a via is connected to the contact in order to couple the gate extension to a frontside interconnect. Technical effects and technical solutions include providing frontside access and control to the lower gate structure of the lower transistor in the stacked transistors.

In addition to one or more of the features described above or below, or as an alternative, further embodiments disclose a cavity in the shallow trench isolation region is filled with the gate extension. Technical effects and technical solutions provide the gate extension that is utilized to provide individual gate control for the lower transistor in the stacked transistors.

In addition to one or more of the features described above or below, or as an alternative, further embodiments disclose the first stacked transistors comprise a bottom dielectric isolation layer such that the gate extension extends below the bottom dielectric isolation layer. Technical effects and technical solutions provide the gate extension that is utilized to provide individual gate control for the lower transistor in the stacked transistors.

Embodiments of the present disclosure are directed to a semiconductor structure. The semiconductor structure includes first stacked transistors having a first upper transistor over a first lower transistor and second stacked transistors adjacent to the first stacked transistors on a first side. A gate structure includes a gate extension into a shallow trench isolation region, where a non-conductive frontside gate cut through the gate structure isolates the first stacked transistors and the second stacked transistors, where a contact through the non-conductive frontside gate cut contacts the gate extension and is coupled to the first lower transistor. The semiconductor structure includes a first shallow non-conductive frontside gate cut contacts the non-conductive frontside gate cut on the first side of the first stacked transistors, and a second shallow non-conductive frontside gate cut contacts a non-conductive backside gate cut on a second side of the first stacked transistors, the second side being opposite the first side. As technical effects and technical solutions, the present disclosure provides independent gate contact to a lower gate of the lower transistor in the stacked transistors, thereby providing independent gate control for upper and lower transistors in the stacked transistors. Advantageously, the present disclosure isolates the upper and lower gates of the upper and lower transistors in the stacked transistors from neighboring stacked transistors.

In addition to one or more of the features described above or below, or as an alternative, further embodiments disclose third stacked transistors are positioned on the second side of the first stacked transistors. Technical effects and technical solutions include separating the first stacked transistors from neighboring stacked transistors.

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

The MOSFET is a transistor used for amplifying or switching electronic signals. The MOSFET has a source, a drain, and a metal gate electrode. The metal gate is electrically insulated from the main semiconductor n-channel or p-channel by a thin layer of insulating material, for example, silicon dioxide or glass, which makes the input resistance of the MOSFET relatively high. The gate voltage controls whether the current path from the source to the drain is an open circuit (“off”) or a resistive path (“on”). N-type field effect transistors (NFET) and p-type field effect transistors (PFET) are two types of complementary MOSFETs. The NFET includes n-doped source and drain junctions and uses electrons as the current carriers. The PFET includes p-doped source and drain junctions and uses holes as the current carriers.

The nanowire or nanosheet MOSFET is a type of MOSFET that uses multiple stacked nanowires/nanosheets to form multiple channel regions. The gate regions of a nanosheet MOSFET are formed by wrapping gate stack materials around the multiple nanowire/nanosheet channels. This configuration is known as a gate-all-around (GAA) FET structure. The nanowire/nanosheet MOSFET device mitigates the effects of short channels and reduces drain-induced barrier lowering.

The GAA nanosheet FET structures can provide superior electrostatics. In contrast to known Fin-type FET (FinFET) structures in which the fin element of the transistor extends “up” out of the transistor, nanosheet FET designs implement the fin as a silicon nanosheet/nanowire. In a known configuration of a GAA nanosheet FET, a relatively small FET footprint is provided by forming the channel region as a series of nanosheets (i.e., silicon nanowires). A known GAA configuration includes a source region, a drain region, and stacked nanosheet channels between the source and drain regions. A gate surrounds the stacked nanosheet channels and regulates electron flow through the nanosheet channels between the source and drain regions. GAA nanosheet FETs are fabricated by forming alternating layers of channel nanosheets and sacrificial nanosheets. The sacrificial nanosheets are released from the channel nanosheets before the FET device is finalized.

Turning now to an overview of technologies that are more specifically relevant to aspects of the present disclosure, ICs are fabricated in a series of stages, including a front-end-of-line (FEOL) stage, a middle-of-line (MOL) stage, and a back-end-of-line (BEOL) stage. The process flows for fabricating modern ICs are often identified based on whether the process flows fall in the FEOL stage, the MOL stage, or the BEOL stage. Generally, the FEOL stage is where device elements (e.g., transistors, capacitors, resistors, etc.) are patterned in the semiconductor substrate/wafer. The FEOL stage processes include wafer preparation, isolation, gate patterning, and the formation of wells, source/drain (S/D) regions, extension junctions, silicide regions, and liners. The MOL stage typically includes process flows for forming the contacts (e.g., CA) and other structures that communicatively couple to active regions (e.g., gate, source, and drain) of the device element. For example, the silicidation of source/drain regions, as well as the deposition of metal contacts, can occur during the MOL stage to connect the elements patterned during the FEOL stage. Layers of interconnections (e.g., metallization layers) are formed above these logical and functional layers during the BEOL stage to complete the IC. Most ICs need more than one layer of wires to form all the necessary connections, and as many as 5-12 layers are added in the BEOL process. The various BEOL layers are interconnected by vias that couple from one layer to another. Insulating dielectric materials are used throughout the layers of an IC to perform a variety of functions, including stabilizing the IC structure and providing electrical isolation of the IC elements. For example, the metal interconnecting wires in the BEOL region of the IC are isolated by dielectric layers to prevent the wires from creating a short circuit with other metal layers.

One or more embodiments provide independent gate contact connection for stacked transistors. Stacked transistors include an upper transistor above a lower transistor. Adjacent stacked transistors includes one set of stacked transistors adjacent to another set of stacked transistors. A technique includes forming a gate extension into a shallow trench isolation region between stacked transistors in which the gate extension is connected to a lower transistor, forming a replacement gate into the gate extension region, and forming a deep-via-contact to contact the lower gate by landing over the gate extension region. The technique includes forming additional gate cuts or spacer structures to isolate the lower gate of the lower transistor from the upper gate of the upper transistor, and forming a backside contact and backside power delivery network (BSPDN). The technical effects and technical solutions provide an independent gate contact for a lower transistor versus an upper transistor of the stacked transistors, when the stacked transistors are adjacent to neighboring stacked transistors.

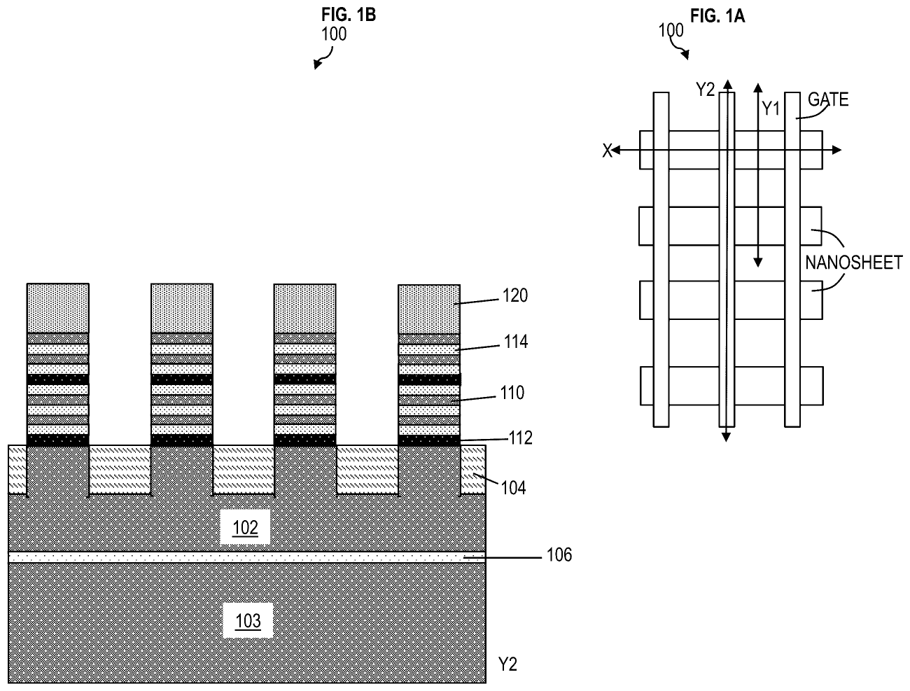

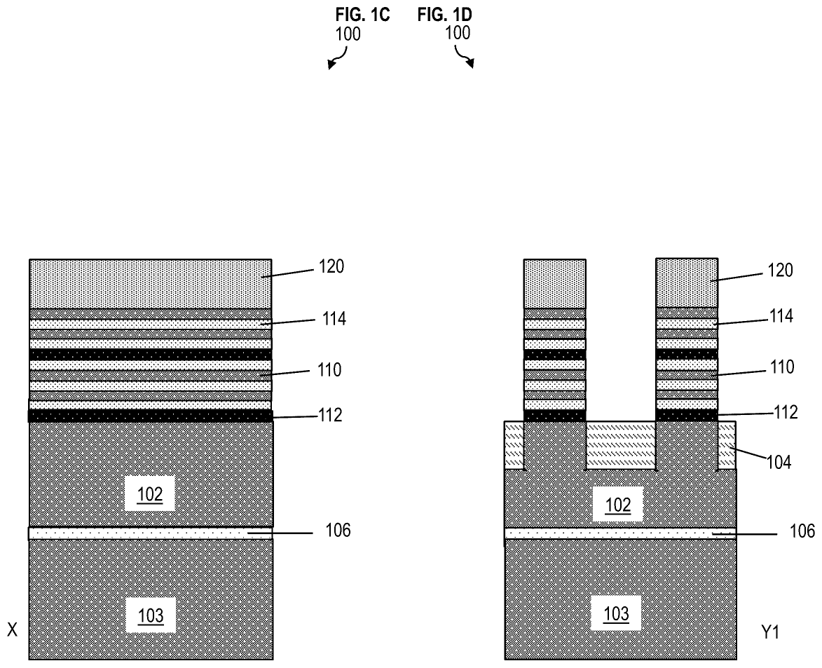

Turning now to a more detailed description of aspects of the present invention, FIG. 1A depicts a top view of a simplified illustration of a portion of an integrated circuit (IC) 100, FIG. 1B depicts a cross-sectional view taken along Y2 of the IC 100, FIG. 1C depicts a cross-sectional view taken along X of the IC 100, and FIG. 1D depicts a cross-sectional view taken along Y1. For ease of understanding, some layers may be omitted from the top view so as not to obscure the figure and to view layers underneath. As such, the top view is intended to provide a simplified illustration and a general orientation, but the top view is not intended to be a complete representation of the device. Standard semiconductor fabrication techniques can be utilized to fabricate the IC 100 as understood by one of ordinary skill in the art. Any suitable lithography processes including deposition techniques and etching techniques can be utilized herein.

FIGS. 1A, 1B, 1C, and 1D depict the IC 100 having a wafer where several fabrication processes have been performed. The figures illustrate the IC 100 after nanosheet stack growth and nanosheet patterning. A nanosheet stack of semiconductor layers 110 is formed with alternating layers of sacrificial layers 114 formed in between on a substrate 102 (or wafer). Each of the nanosheet stacks includes an upper transistor above a lower transistor. The substrate 102 (or wafer) may be formed of (pure) silicon. Other suitable semiconductor materials can be utilized for the substrate 102. Sacrificial layers 112 are formed in the nanosheet stack as placeholders for a middle dielectric isolation layer and a bottom dielectric isolation layer. One of the sacrificial layers 112 separates upper transistors from the lower transistors, while the other one of the sacrificial layers 112 is on top of the substrate 102. An etch stop layer 106 is between the substrate 102 and a lower substrate 103. The lower substrate 103 may be pure silicon or another suitable material.

The semiconductor layers 110 may include substantially pure silicon. The semiconductor layers 110 will become the channel regions for the nanosheet FET device. The semiconductor layers 110 are nanosheets, and the nanosheets can have a thickness of, for example, 5 nanometers. The thickness of a nanosheet can range from about 2-10 nm, and other ranges are possible.

The sacrificial layers 112 and 114 are formed of silicon germanium (SiGe). In one or more embodiments, the sacrificial layers 114 can include SiGe where germanium has an atomic percent (%) of about 30% and silicon is the remainder. In one or more embodiments, the atomic percent of germanium can range from about 15-35% while silicon is the remainder in the sacrificial layers 114. In one or more embodiments, the sacrificial layers 112 can include SiGe where germanium has an atomic percent (%) of about 60% and silicon is the remainder. In one or more embodiments, the atomic percent of germanium can range from about 50-65% while silicon is the remainder in the sacrificial layers 112. The atomic percent of germanium in sacrificial layers 112 is greater than in sacrificial layers 114, thereby providing etch selectivity.

Using a (patterned) hard mask layer 120, nanosheet patterning has been performed resulting in the nanosheet stacks, and shallow trench isolation (STI) regions 104 are formed in the substrate 102. The STI regions 104 can include low-k dielectric materials, ultra-low-k dielectric materials, etc. The hard mask layer 120 can include a nitride material such as, for example, silicon nitride.

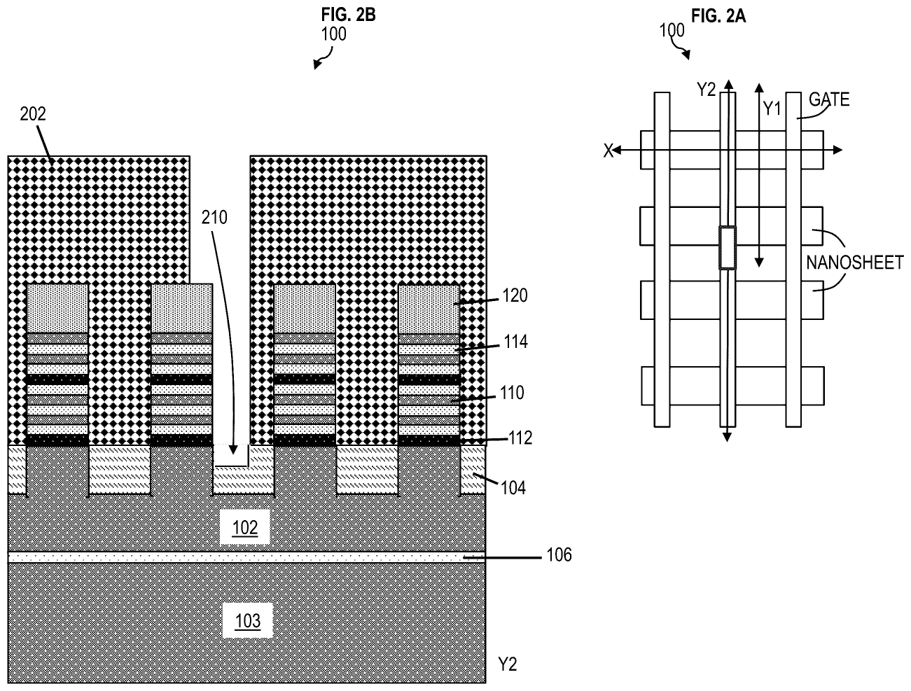

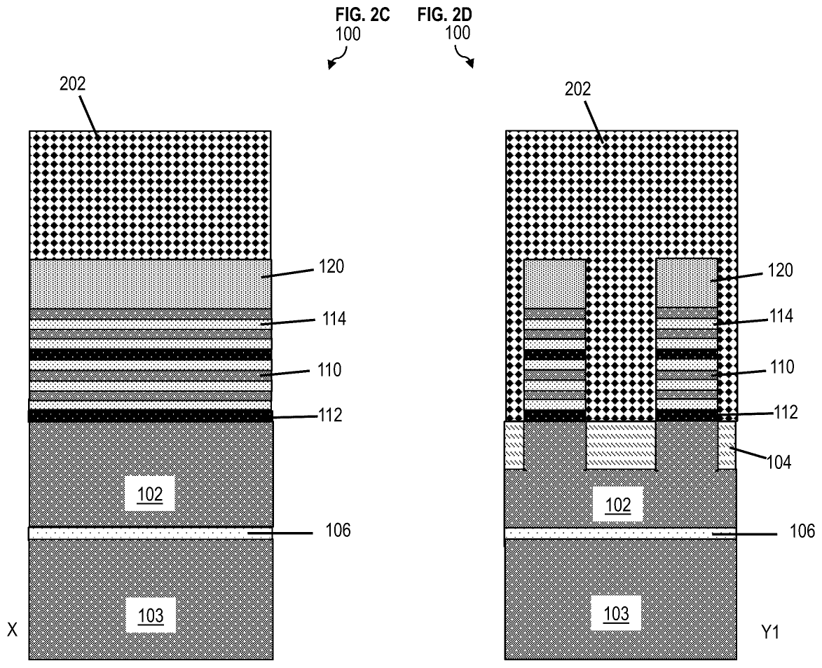

FIGS. 2A, 2B, 2C, and 2D depict the IC 100 after backside independent gate patterning. The hard mask layer 120 is removed. A block mask 202 is formed and patterned. The block mask 202 can include a stack of materials. Example materials of the block mask 202 can include an organic patterning layer (OPL), antireflective coating, and/or a photoresist layer, along with other known materials.

Using the (patterned) block mask 202, etching is performed to create a cavity 210 in an STI region 104 between two adjacent nanosheet stacks of stacked transistors. The cavity 210 is a result of removing a portion of the material in the STI region 104 in preparation to form a gate extension.

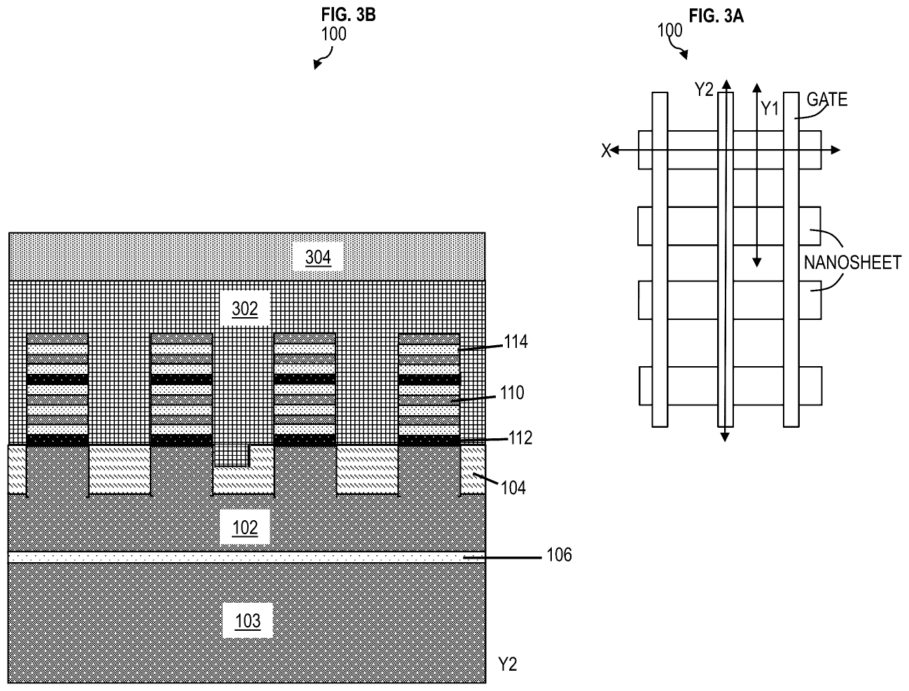

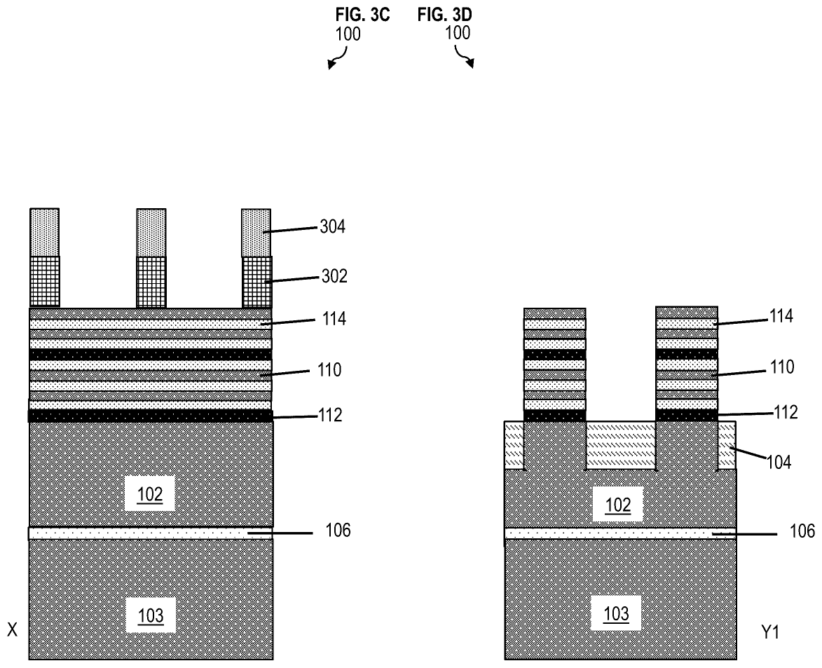

FIGS. 3A, 3B, 3C, and 3D depict the IC 100 after dummy gate formation. The block mask 202 is removed. The block mask 202 can be stripped or removed by ashing. A dummy gate 302 is formed and patterned using a (patterned) hard mask layer 304. Material of the dummy gate 302 is formed in the cavity 210. The hard mask layer 304 can include any materials of hard mask layer 304. The dummy gate 302 can include amorphous silicon, polysilicon, etc.

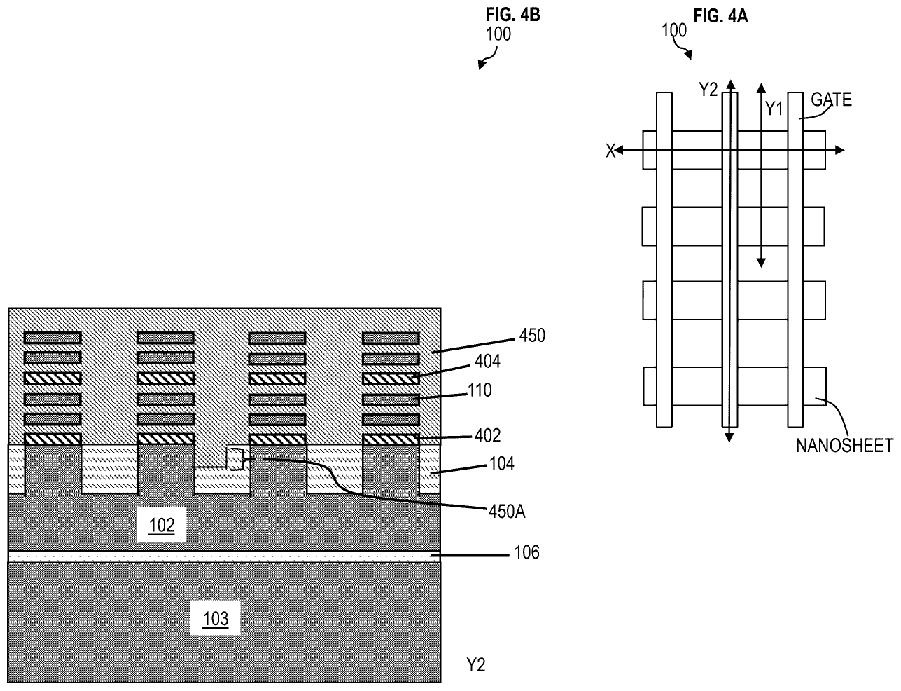

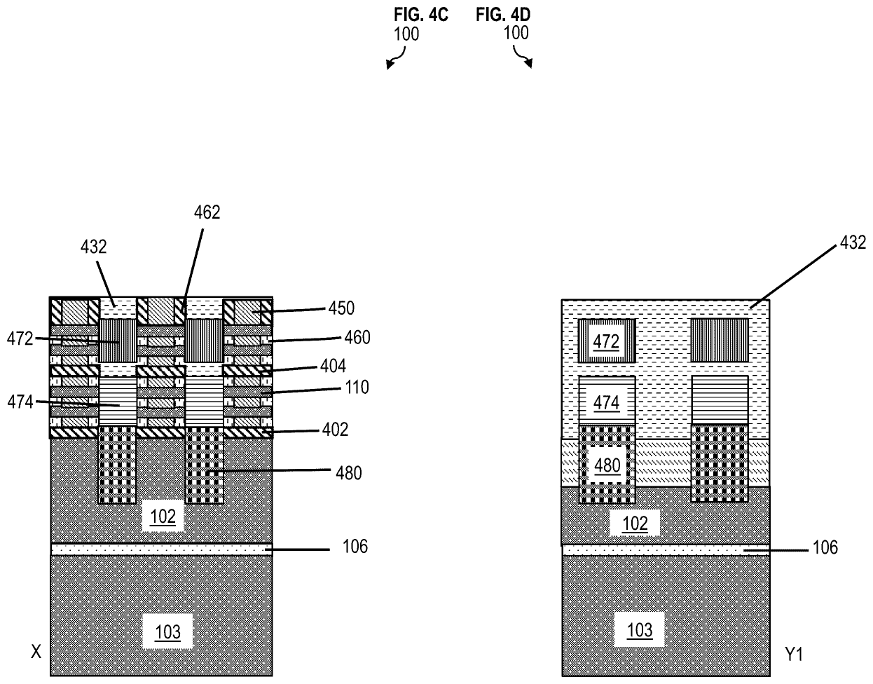

FIGS. 4A, 4B, 4C, and 4D depict the IC 100 after replacement metal gate formation. Etching and gate spacer deposition are performed resulting in gate spacers 462, bottom dielectric isolation layer 402, and middle dielectric isolation layer 404. The sacrificial layers 112 are selectively removed, leaving an empty cavity (not shown). It is noted that the sacrificial layers 112 have the highest atomic percent of germanium in the silicon germanium material, and the sacrificial layers 112 can be selectively etched versus the sacrificial layers 114 and the semiconductor layers 110. After etching, spacer material is deposited at the sides of the dummy gate 302 as well as into the empty cavity left after removal of the sacrificial layers 112, resulting in gate spacers 462, bottom dielectric isolation layer 402 and middle dielectric isolation layer 404. Example materials of the gate spacers 462, the bottom dielectric isolation layer 402, and middle dielectric isolation layer 404 can include nitride materials, such as SIN, SiBCN, SiOCN, SiOC, etc.

Nanosheet pulldown and inner space formation are performed. Directional etching is performed while using the hard mask layer 304 and the gate spacers 462 as a protective mask, in order to trim the nanosheet stack. As a result of the etching, the unprotected portions of the semiconductor layers 110 and the sacrificial layers 114 are removed. To form inner spacers 460, isotropic etching is performed to selectively remove end portions of the sacrificial layers 114 resulting in cavities at the ends. Inner spacer material is deposited to fill the cavities, and etching is performed to remove the excess spacer material, resulting in the inner spacers 460 on the ends of the sacrificial layers 114. Example materials of the inner spacers 460 can include nitrides, low-k dielectric materials, etc. Example materials of the inner spacers 460 may include SiBCN, SiOCN, SiN, SiOC, SiC, etc.

It is noted that the directional etching using the hard mask layer 304 and the gate spacers 462 is performed to create cavities (not shown) in the substrate 102, and backside contact placeholders 480 are formed in those cavities. Epitaxial material is grown to form lower source/drain regions 474, material is deposited to form interlayer dielectric (ILD) layer 432, and epitaxial material is grown to form upper source/drain regions 472. Further material of the ILD layer 432 can be deposited. The epitaxial materials of the source/drain regions can be doped with p-type dopants and n-type dopants to form p-type source/drain regions and n-type source/drain regions respectively. The ILD layer 432 can include low-k dielectric materials, ultra-low-k dielectric materials, etc. The backside contact placeholders 480 can include silicon germanium.

Planarization may be performed by, for example, chemical mechanical polishing/planarizing (CMP). Dummy gate removal and hard mask removal are performed. Replacement high-k metal gate formation is performed, resulting in a gate structure 450 having a gate extension 450A into the STI region 104. The gate structure 450 includes one or more dielectric materials, such as a high-k dielectric material, surrounding the semiconductor layers 110 and work function materials around the dielectric materials. The gate structure may be referred to as a high-k metal gate.

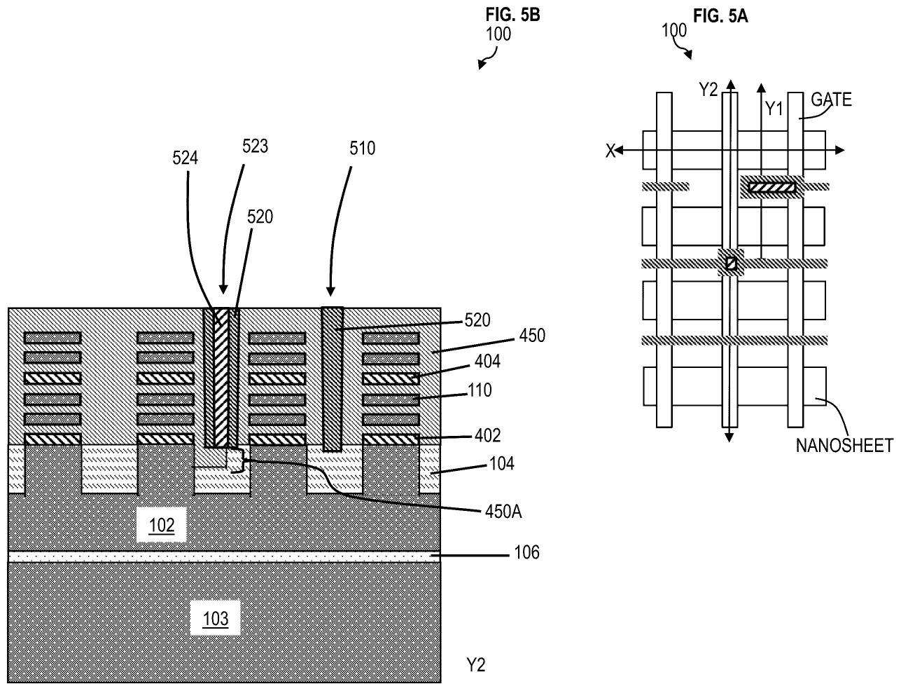

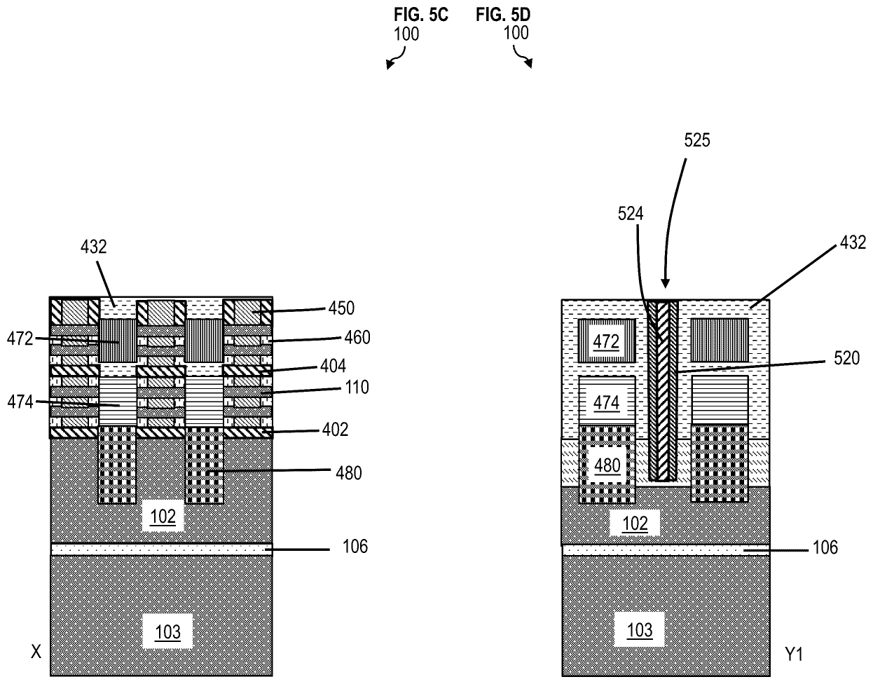

FIGS. 5A, 5B, 5C, and 5D depict the IC 100 after gate cut formation and deep via formation. Lithography is performed to etch trenches. Deposition is performed to deposit non-conductive material 520 into the trenches, resulting in non-conductive frontside cuts. For example, a corresponding trench (not shown) is used to form non-conductive frontside gate cut 510, which includes the non-conductive material 520 that is pinched off in the trench. A corresponding trench (not shown) is used to form a frontside gate cut 523, which includes the non-conductive material 520 surrounding conductive material 524. The conductive material 524 of the frontside gate cut 523 is in contact with the gate extension 450A. Similarly, a corresponding trench (not shown) is used to form a frontside gate cut 525, which includes the non-conductive material 520 surrounding conductive material 524.

In one or more embodiments, the trenches may be formed concurrently, and dielectric material is deposited. When depositing the non-conductive material, some trenches will pinch off resulting in non-conductive frontside cuts. Other trenches or vias are designed to have an opening remain such that conductive material can be deposited subsequently in the opening, resulting in deep via contacts such as the frontside gate cuts 523 and 525 with the conductive material 524.

Example materials of the non-conductive material 520 can include low-k dielectric materials, ultra-low-k dielectric materials, etc., which are intended to be non-conducting materials. Example materials of the non-conductive material 520 can include nitrides including silicon nitride, etc.

Example materials of the conductive material 524 can include metals as well as metal alloys. Example metals or metal alloys can include tungsten, titanium, titanium nitride, nickel, copper, gold, aluminum, etc., with appropriate liners.

The non-conductive frontside gate cut 510, the frontside gate cut 523, and the frontside gate cut 525 separate various stacked transistors from their neighboring stacked transistors.

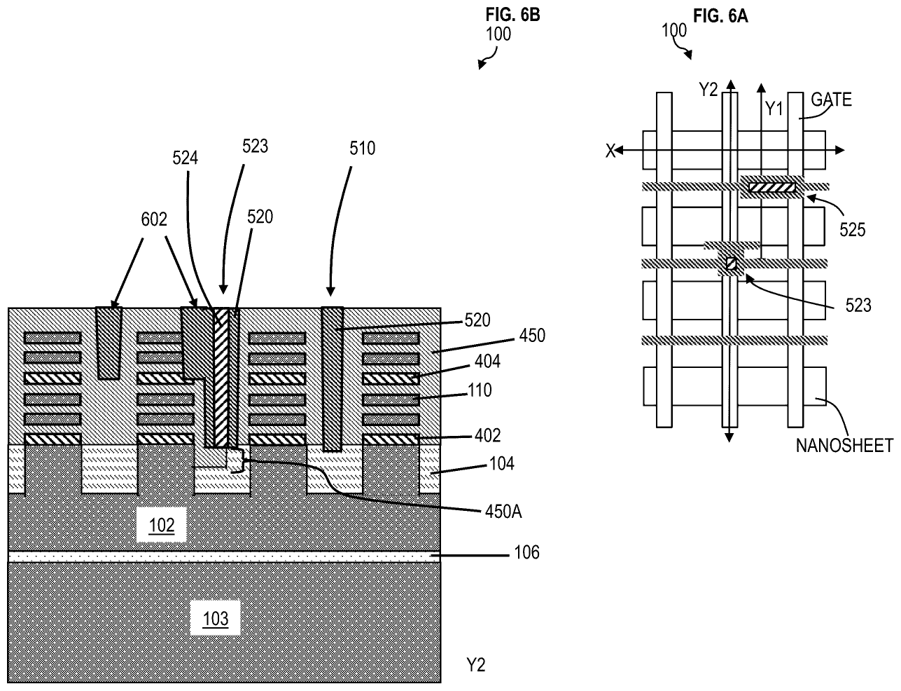

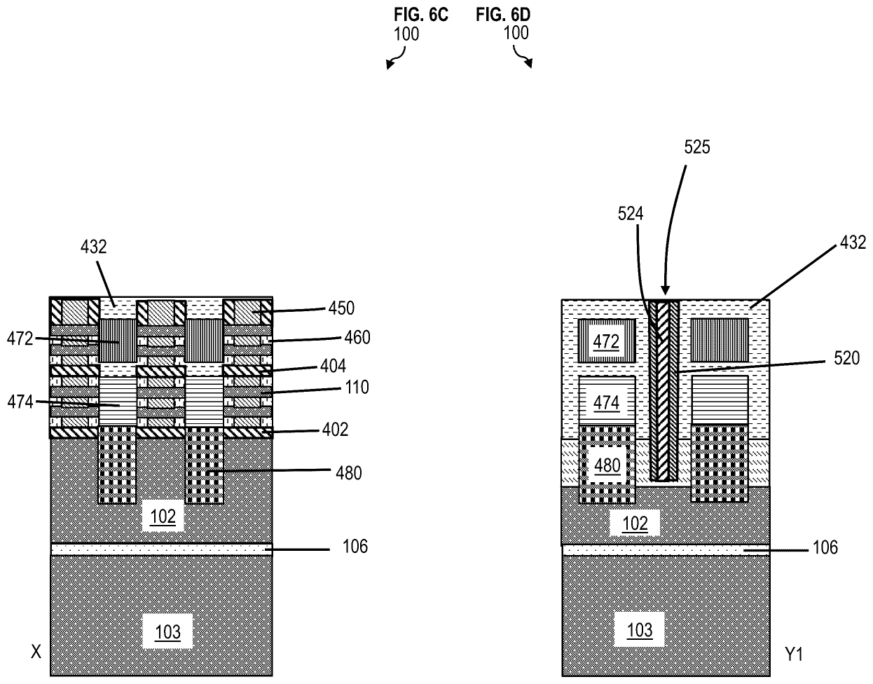

FIGS. 6A, 6B, 6C, and 6D depict the IC 100 after shallow frontside cut formation. Lithography is performed to etch trenches. Deposition is performed to deposit non-conductive material 520 into the trenches, resulting in non-conductive frontside cuts 602. The non-conductive frontside cuts 602 are shallow because their depth is less than the depth of the non-conductive frontside gate cut 510, the frontside gate cut 523, and the frontside gate cut 525.

Further, as a result of forming a shallow trench (not shown) adjacent to the frontside gate cut 523, a portion of semiconductor layers 110 may be removed from an upper transistor and a portion of a middle dielectric isolation layer 404 may be removed; accordingly, the shallow trench is filled with the non-conductive material 520 so as to be connected to and/or merged with the frontside gate cut 523.

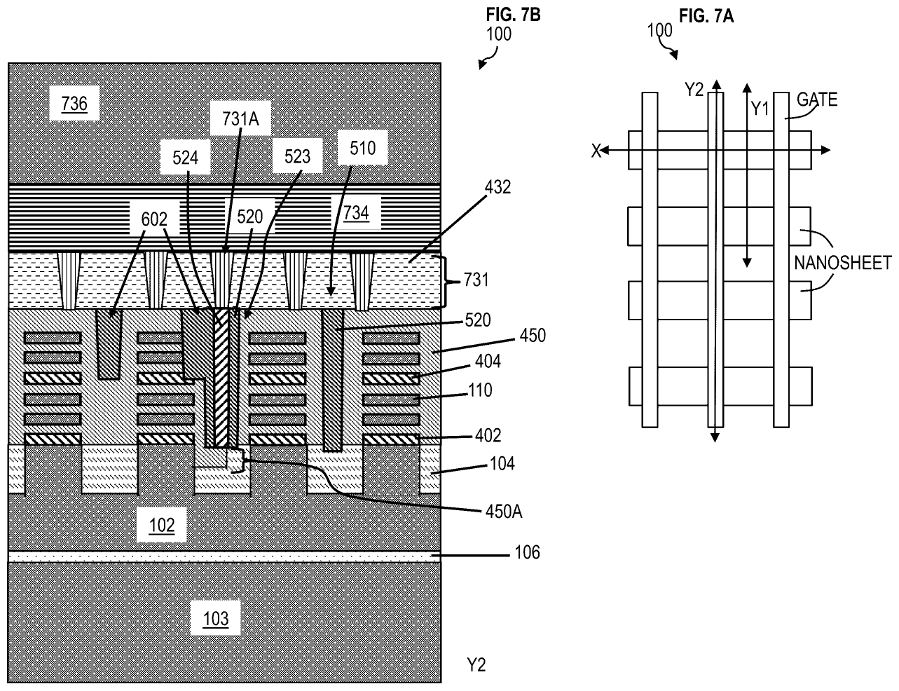

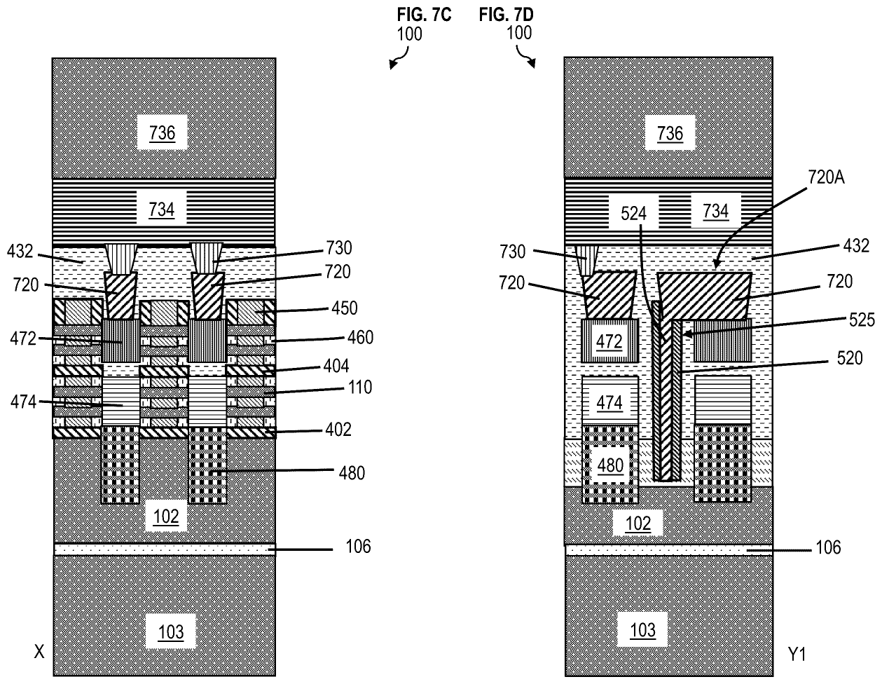

FIGS. 7A, 7B, 7C, and 7D depict the IC 100 after middle-of-line processing, backend-of-line formation, and carrier wafer bonding. Additional material for the ILD layer 432 is deposited, and lithography is performed to form cavities (not shown) which are filled with conductive material to form source/drain contacts 720. To highlight one of the source/drain contacts 720, one source/drain contact is designated as source/drain contact 720A. While etching one of the cavities, a portion of the non-conductive material 520 of the frontside gate cut 525 is removed to expose the (inner) conductive material 524; this is so that part of the source/drain contact 720A is formed in contact with the (inner) conductive material 524 of the frontside gate cut 525. Also, the source/drain contact 720A is formed in contact with an upper source/drain region 472.

After depositing additional material for the ILD layer 432, lithography is performed to form cavities, and the cavities are filled with conductive material to form conductive vias 730 and conductive vias 731. The conductive vias 730 are in contact with the source/drain contacts 720. One of the conductive vias 731 is designated as conductive via 731A for illustration. The conductive via 731A is formed to contact the conductive material 524 of the frontside gate cut 523, thereby providing frontside access to the lower gate of the lower transistor in the stacked transistors.

BEOL layers are formed to result in a (BEOL) interconnect 734, and a carrier wafer 736 is bonded on the interconnect 734.

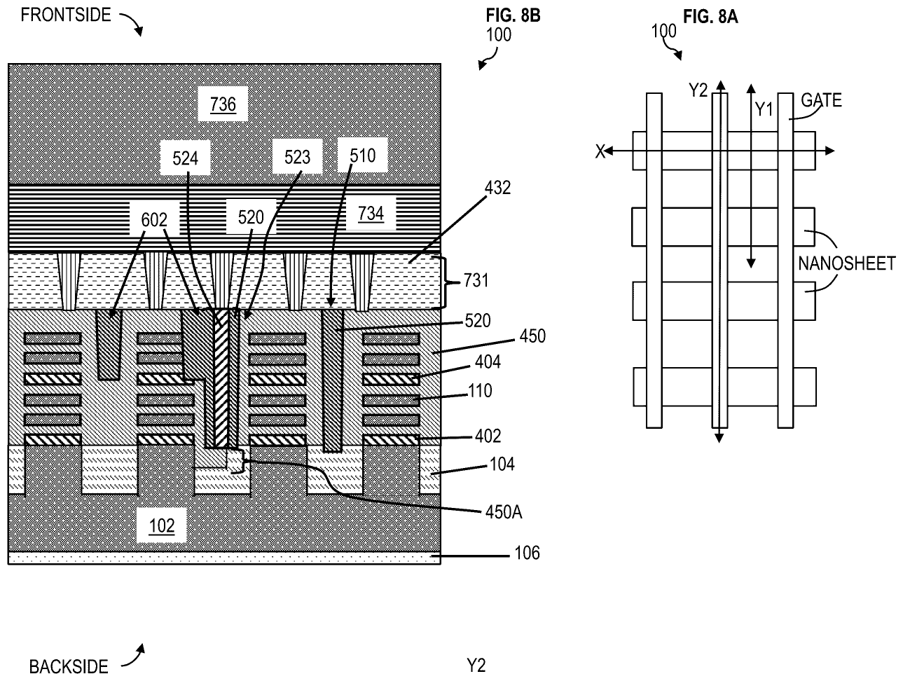

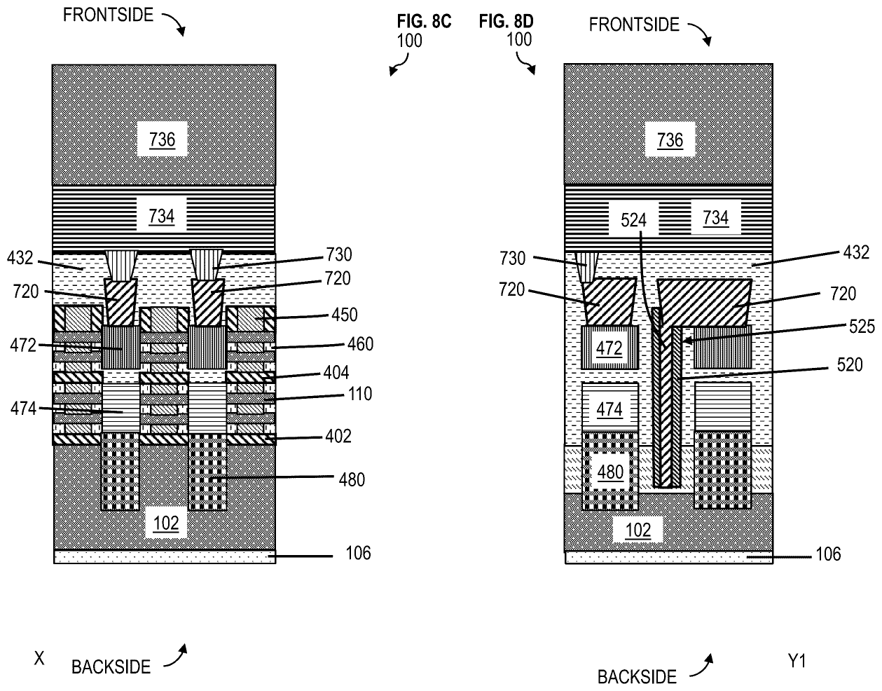

FIGS. 8A, 8B, 8C, and 8D depict the IC 100 after lower substrate removal. Although it is understood that fabrication processes are formed on the backside of the wafer by flipping the wafer, the orientation of the figures is not flipped so as to assist the reader. Etching is performed to remove the lower substrate 103, and etching stops on the etch stop layer 106.

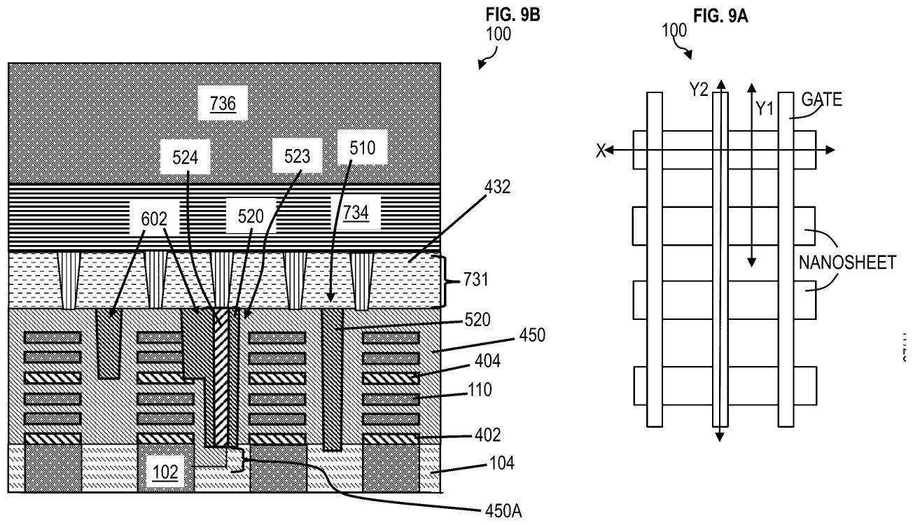

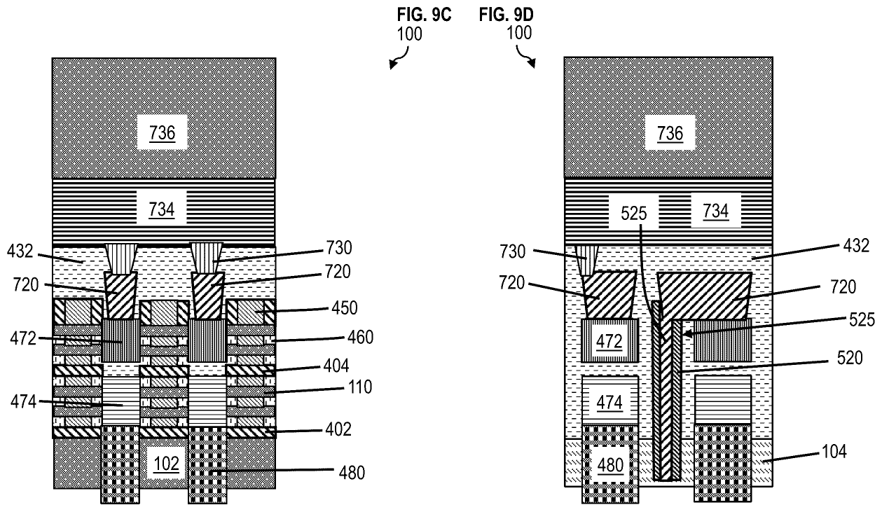

FIGS. 9A, 9B, 9C, and 9D depict the IC 100 after removing the etch stop layer and recessing the substrate. The etch stop layer 106 can be stripped. Etching is performed to recess the substrate 102 such that the backside contact placeholders 480 are exposed.

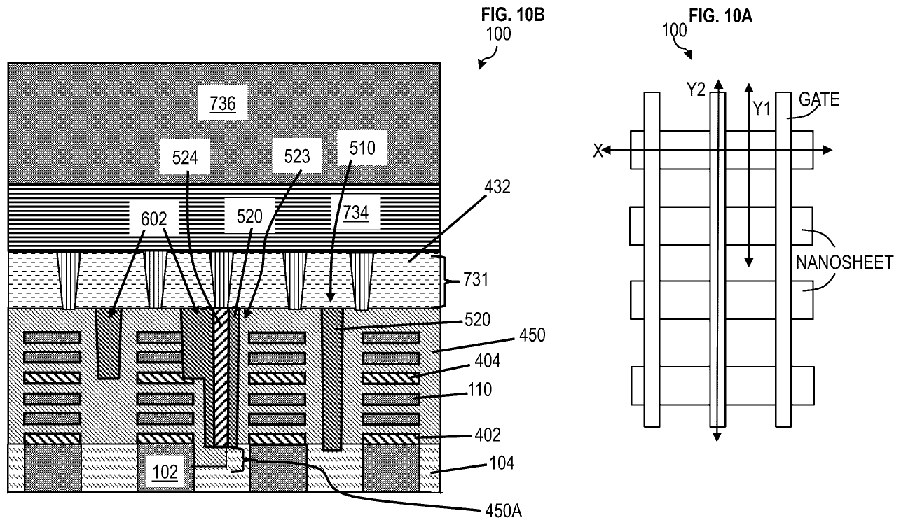

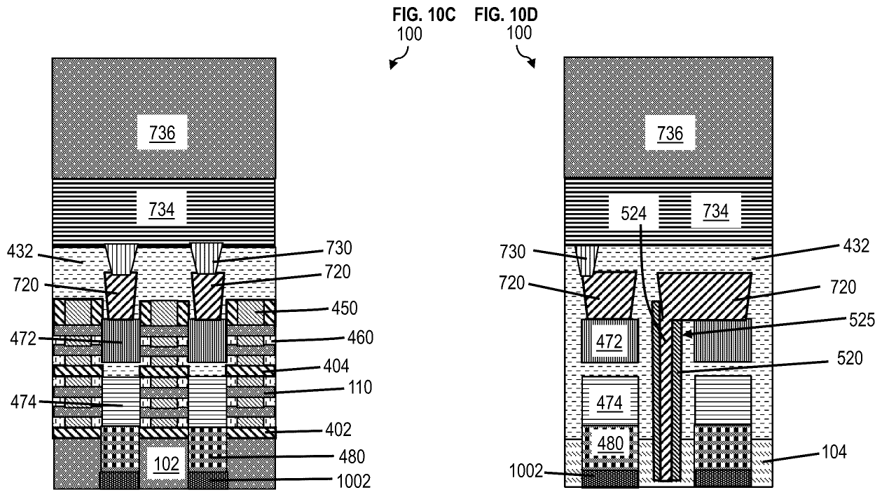

FIGS. 10A, 10B, 10C, and 10D depict the IC 100 after recessing the placeholders and forming a protective cap. Etching is performed to selectively recess the backside contact placeholders 480 to result cavities, and a protective cap 1002 is formed in the cavities. The protective cap 1002 may include nitride materials, such as silicon nitride.

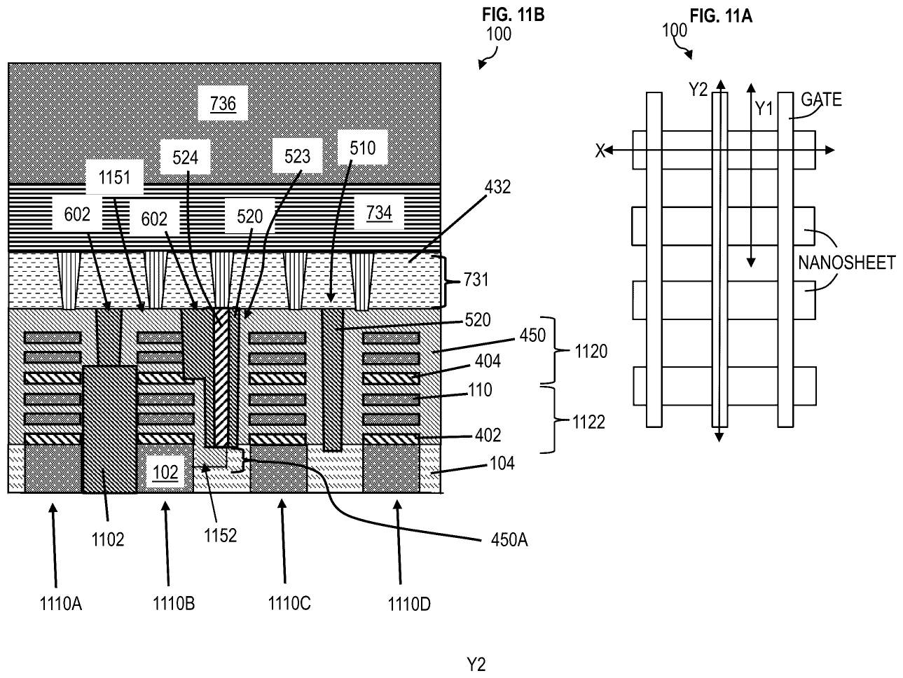

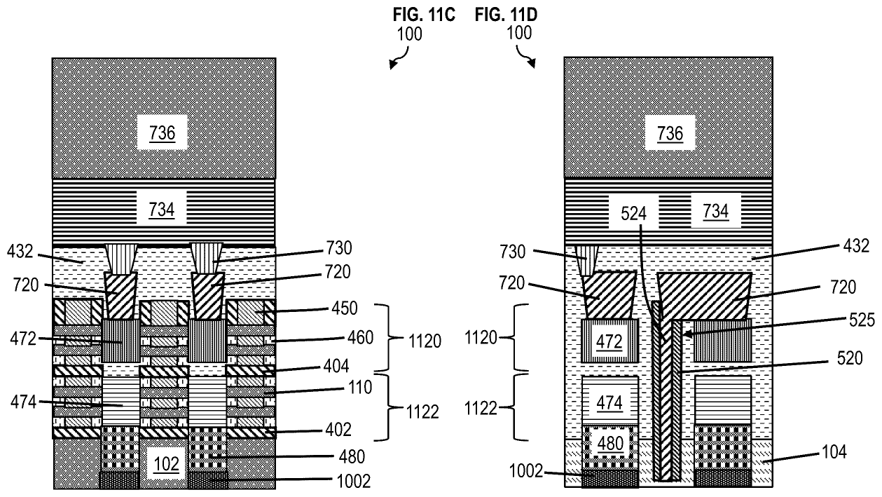

FIGS. 11A, 11B, 11C, and 11D depict the IC 100 after forming a backside cut for independent gate formation. Lithography is performed to form a non-conductive backside cut 1102. For example, a block mask (not shown) is patterned, and etching is performed from the backside to open a cavity (not shown) to expose a bottom surface of the (shallow) non-conductive frontside cut 602. Non-conductive material 520 is deposited in the cavity to form the non-conductive backside cut 1102 in contact with the (shallow) non-conductive frontside cut 602. Planarization/polishing may be performed using, for example, CMP.

Example stacked transistors 1110A, 1110B, 1110C, and 1110D each include an upper transistor 1120 above a lower transistor 1122. In one or more embodiments, one transistor can be a PFET while the other is an NFET. In one or more embodiments, both the upper and lower transistors can be PFETs or both can be NFETs.

For explanation purposes and not limitation, the stacked transistors 1110B will be highlighted. It should be appreciated that the novel independent gate contact and novel isolation of the upper transistor from the lower transistor can apply to and/or be formed for any of the neighboring stacked transistors. With respect to the left side of stacked transistors 1110B, the combination of the (shallow) non-conductive frontside cut 602 and the non-conductive backside cut 1102 isolates the stacked transistors 1110B from the stacked transistors 1110A, while also isolating the upper transistor 1120 from the lower transistor 1122 of the stacked transistors 1110B. Analogously, with respect to the right side of the stacked transistors 1110B, the combination of the (shallow) non-conductive frontside cut 602 and the frontside gate cut 523 isolates the stacked transistors 1110B from the stacked transistors 1110C, while also isolating the upper transistor 1120 from the lower transistor 1122 of the stacked transistors 1110B. This novel arrangement with respect to the stacked transistors 1110B allows the frontside gate cut 523 to serve as independent gate contact for the lower transistor 1122 of the stacked transistors 1110B, by the conductive material 524 of the frontside gate cut 523 and the gate extension 450A. As seen in FIG. 11B, an (independent) upper gate structure 1151 and lower gate structure 1152 of the gate structure 450 respectively of the upper transistor 1120 and the lower transistor 1122 of the stacked transistors 1110B can both be controlled from the frontside by respective conductive vias 731.

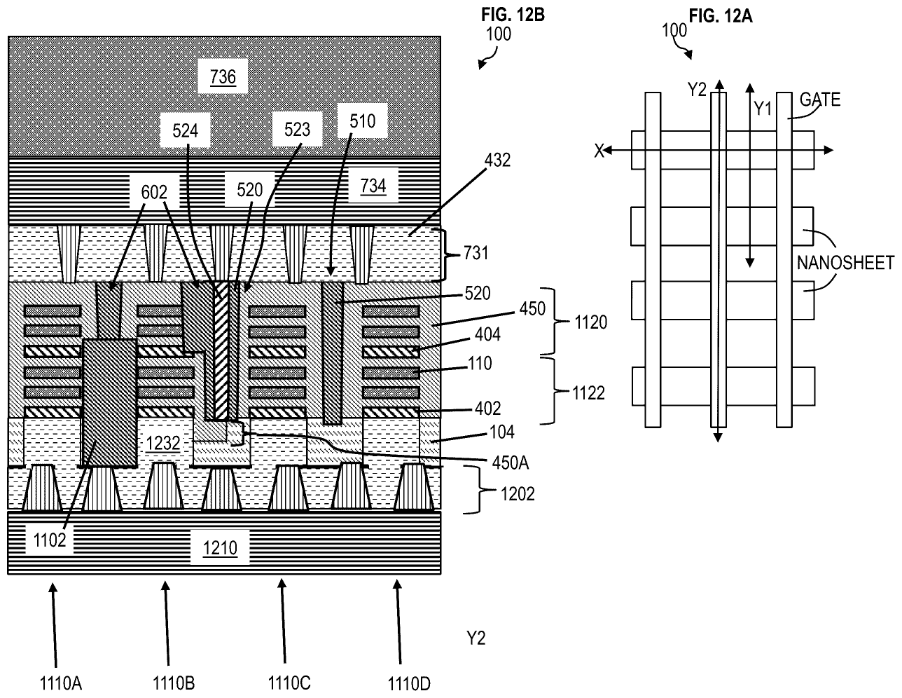

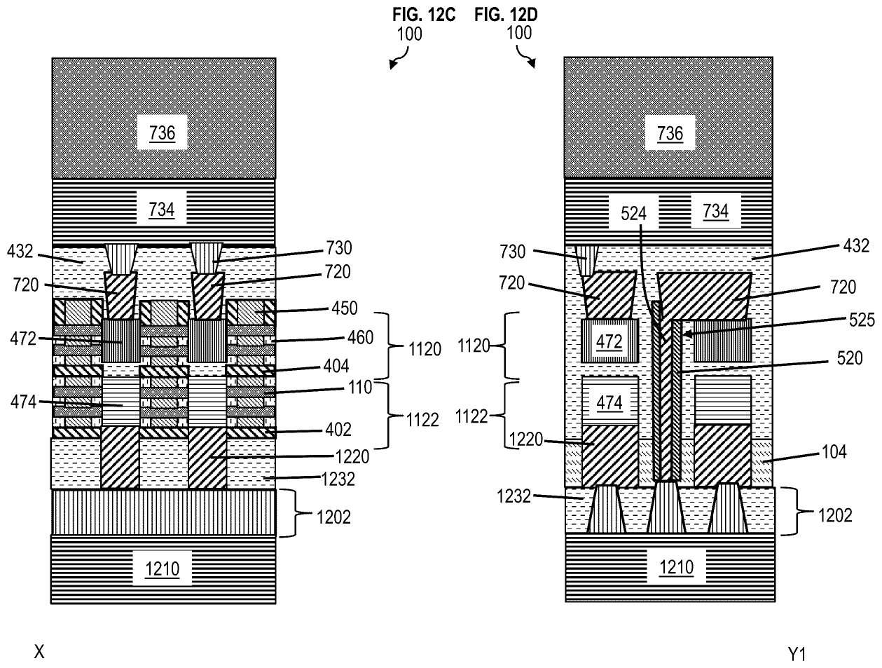

FIGS. 12A, 12B, 12C, and 12D depict the IC 100 after formation of a backside power delivery network (BSPDN). The remaining silicon of substrate 102 is removed. Backside ILD layer 1232 is formed. The protective cap 1002 and backside contact placeholders 480 are removed, such that backside source/drain contacts 1220 are formed. Additional material of the backside ILD layer 132 is deposited. Lithography is performed, and backside conductive vias 1202 are formed in contact with the backside source/drain contacts 1220 in order to serve as power rails. The BSPDN 1210 is formed on the backside conductive vias 1202.

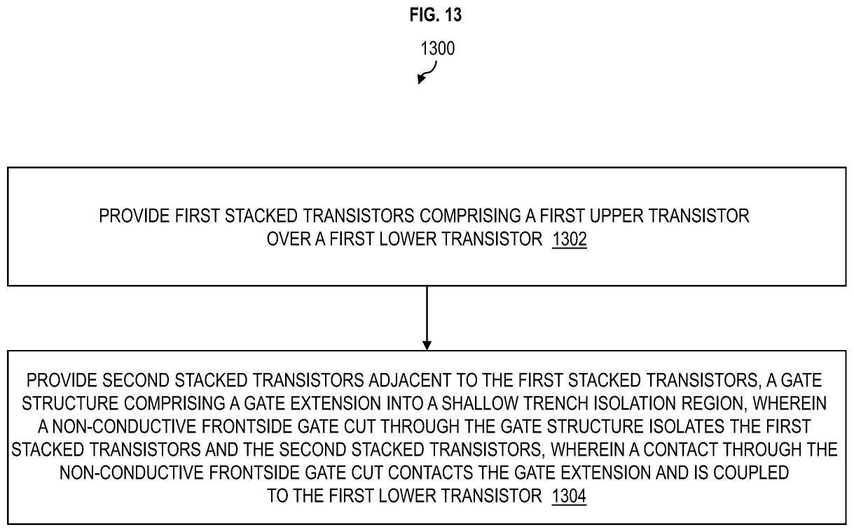

According to one or more embodiments, FIG. 13 is a flowchart of a method 1300 of forming/arranging the IC 100. Reference can be made to any of the figures discussed herein. The method 1300 includes providing first stacked transistors (e.g., stacked transistors 1110B) having a first upper transistor (e.g., upper transistor 1120) over a first lower transistor (e.g., lower transistor 1122) at block 1302. At block 1304, the method 1300 includes providing second stacked transistors (e.g., stacked transistors 1110C) adjacent to the first stacked transistors (e.g., stacked transistors 1110B), a gate structure 450 having a gate extension 450A into a shallow trench isolation region 104, where a (non-conductive) frontside gate cut 523 through the gate structure 450 isolates the first stacked transistors (e.g., stacked transistors 1110B) and the second stacked transistors (e.g., stacked transistors 1110C), where a contact (e.g., conductive material 524) through the (non-conductive) frontside gate cut 523 contacts the gate extension 450A and is coupled to the first lower transistor (e.g., lower transistor 1122).

Further, the (non-conductive) frontside gate cut 523 isolates/divides the gate structure 450 into an upper gate structure 1151 and a lower gate structure 1152, the lower gate structure 1152 including the gate extension 450A. The first upper transistor 1120 includes an upper gate structure 1151 and the first lower transistor includes a lower gate structure 1152, the upper and lower gate structures being formed by the (non-conductive) frontside gate cut 523.

Additionally, the first stacked transistors (e.g., stacked transistors 1110B) include a middle dielectric isolation layer 404 separating the first upper transistor 1120 from the first lower transistor 1122. A non-conductive backside gate cut 1102 is in contact with the middle dielectric isolation layer 404, thereby forming a lower gate structure 1152 of the first lower transistor 1122. A (shallow) non-conductive frontside gate cut 602 is in contact with both the middle dielectric isolation layer 404 and the (non-conductive) frontside gate cut 523.

A via (e.g., conductive via 731) is connected to the contact (e.g., conductive material 524) in order to couple the gate extension 450A to a frontside interconnect (e.g., interconnect 734). A cavity 210 in the shallow trench isolation region 104 is filled with the gate extension 450A. The first stacked transistors include a bottom dielectric isolation layer 402 such that the gate extension 450A extends below the bottom dielectric isolation layer 402.

According to one or more embodiments, a method includes providing an IC 100. The method includes providing first stacked transistors (e.g., stacked transistors 1110B) having a first upper transistor (e.g., upper transistor 1120) over a first lower transistor (e.g., lower transistor 1122). The method includes providing second stacked transistors (e.g., stacked transistors 1110C) adjacent to the first stacked transistors (e.g., stacked transistors 1110B) on a first side, a gate structure 450 including a gate extension 450A into a shallow trench isolation region 104, where a (non-conductive) frontside gate cut 523 through the gate structure 450 isolates the first stacked transistors (e.g., stacked transistors 1110B) and the second stacked transistors (e.g., stacked transistors 1110C), where a contact through the (non-conductive) frontside gate cut 523 contacts the gate extension 450A and is coupled to the first lower transistor (e.g., lower transistor 1122). The method includes forming a (first shallow) non-conductive frontside gate cut 602 that contacts the (non-conductive) frontside gate cut 523 on the first side of the first stacked transistors (e.g., stacked transistors 1110B). The method includes a (second shallow) non-conductive frontside gate cut 602 contacts a non-conductive backside gate cut 1102 on a second side of the first stacked transistors (e.g., stacked transistors 1110B), the second side being opposite the first side.

Further, third stacked transistors (e.g., stacked transistors 1110A) are positioned on the second side of the first stacked transistors (e.g., stacked transistors 1110B).

As discussed herein, gate material is formed around the semiconductor layers. The gate material includes high-k material and work function material generally referred to as a high-k metal gate (HKMG). Techniques for forming HKMG in gate openings are well-known in the art and, thus, the details have been omitted in order to allow the reader to focus on the salient aspects of the disclosed methods. However, it should be understood that such HKMG will generally include formation of one or more gate dielectric layers (e.g., an inter-layer (IL) oxide and a high-k gate dielectric layer), which are deposited so as to line the gate openings, and formation of one or more metal layers, which are deposited onto the gate dielectric layer(s) so as to fill the gate openings. The materials and thicknesses of the dielectric and metal layers used for the HKMG can be preselected to achieve desired work functions given the conductivity type of the FET. To avoid clutter in the drawings and to allow the reader to focus on the salient aspects of the disclosed methods, the different layers within the HKMG stack are not illustrated. For explanation purposes, a high-k gate dielectric layer can be, for example, a dielectric material with a dielectric constant that is greater than the dielectric constant of silicon dioxide (i.e., greater than 3.9). Exemplary high-k dielectric materials include, but are not limited to, hafnium (Hf)-based dielectrics (e.g., hafnium oxide, hafnium silicon oxide, hafnium silicon oxynitride, hafnium aluminum oxide, etc.) or other suitable high-k dielectrics (e.g., aluminum oxide, tantalum oxide, zirconium oxide, etc.). Optionally, the metal layer(s) can include a work function metal that is immediately adjacent to the gate dielectric layer and that is preselected in order to achieve an optimal gate conductor work function given the conductivity type of the nanosheet-FET. For example, the optimal gate conductor work function for the PFETs can be, for example, between about 4.9 eV and about 5.2 eV. Exemplary metals (and metal alloys) having a work function within or close to this range include, but are not limited to, ruthenium, palladium, platinum, cobalt, and nickel, as well as metal oxides (aluminum carbon oxide, aluminum titanium carbon oxide, etc.) and metal nitrides (e.g., titanium nitride, titanium silicon nitride, tantalum silicon nitride, titanium aluminum nitride, tantalum aluminum nitride, etc.). The optimal gate conductor work function for NFETs can be, for example, between 3.9 eV and about 4.2 eV. Exemplary metals (and metal alloys) having a work function within or close to this range include, but are not limited to, hafnium, zirconium, titanium, tantalum, aluminum, and alloys thereof, such as, hafnium carbide, zirconium carbide, titanium carbide, tantalum carbide, and aluminum carbide. The metal layer(s) can further include a fill metal or fill metal alloy, such as tungsten, a tungsten alloy (e.g., tungsten silicide or titanium tungsten), cobalt, aluminum, or any other suitable fill metal or fill metal.

Although not shown, contact formation and ILD formation are performed. ILD material can be deposited, source/drain contact openings are patterned by conventional lithography, and then metal is deposited to fill the cavities thereby forming metal contacts. A portion of the metal contacts may include silicide, resulting from the interface of the metal material and semiconductor material. The metal contacts are source/drain contacts that are respectively connected to epitaxial source/drain regions.

The ILD material can be SiO2, SiN, a low-k dielectric material or an ultra-low-k dielectric material. Low-k dielectric materials may generally include dielectric materials having a k value of about 3.9 or less. The ultra-low-k dielectric material generally includes dielectric materials having a k value less than 2.5. Unless otherwise noted, all k values mentioned in the present application are measured relative to a vacuum. Exemplary ultra-low-k dielectric materials generally include porous materials such as porous organic silicate glasses, porous polyamide nanofoams, silica xerogels, porous hydrogen silsequioxane (HSQ), porous methylsilsesquioxane (MSQ), porous inorganic materials, porous CVD materials, porous organic materials, or combinations thereof. The ultra-low-k dielectric material can be produced using a templated process or a sol-gel process as is generally known in the art. In the templated process, the precursor typically contains a composite of thermally labile and stable materials. After film deposition, the thermally labile materials can be removed by thermal heating, leaving pores in the dielectric film. In the sol gel process, the porous low-k dielectric films can be formed by hydrolysis and polycondensation of an alkoxide(s) such as tetraetehoxysilane (TEOS).

Various embodiments of the present invention are described herein with reference to the related drawings. Alternative embodiments can be devised without departing from the scope of this invention. Although various connections and positional relationships (e.g., over, below, adjacent, etc.) are set forth between elements in the following description and in the drawings, persons skilled in the art will recognize that many of the positional relationships described herein are orientation-independent when the described functionality is maintained even though the orientation is changed. These connections and/or positional relationships, unless specified otherwise, can be direct or indirect, and the present invention is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The phrase “selective to,” such as, for example, “a first element selective to a second element,” means that the first element can be etched and the second element can act as an etch stop.

As used herein, “p-type” refers to the addition of impurities to an intrinsic semiconductor that creates deficiencies of valence electrons. In a silicon-containing substrate, examples of p-type dopants, i.e., impurities, include but are not limited to: boron, aluminum, gallium and indium.

As used herein, “n-type” refers to the addition of impurities that contributes free electrons to an intrinsic semiconductor. In a silicon containing substrate examples of n-type dopants, i.e., impurities, include but are not limited to antimony, arsenic and phosphorous.

As previously noted herein, for the sake of brevity, conventional techniques related to semiconductor device and integrated circuit (IC) fabrication may or may not be described in detail herein. By way of background, however, a more general description of the semiconductor device fabrication processes that can be utilized in implementing one or more embodiments of the present invention will now be provided. Although specific fabrication operations used in implementing one or more embodiments of the present invention can be individually known, the described combination of operations and/or resulting structures of the present invention are unique. Thus, the unique combination of the operations described in connection with the fabrication of a semiconductor device according to the present invention utilize a variety of individually known physical and chemical processes performed on a semiconductor (e.g., silicon) substrate, some of which are described in the immediately following paragraphs.

In general, the various processes used to form a micro-chip that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device.

As noted above, atomic layer etching processes can be used in the present invention for via residue removal, such as can be caused by via misalignment. The atomic layer etch process provide precise etching of metals using a plasma-based approach or an electrochemical approach. The atomic layer etching processes are generally defined by two well-defined, sequential, self-limiting reaction steps that can be independently controlled. The process generally includes passivation followed selective removal of the passivation layer and can be used to remove thin metal layers on the order of nanometers. An exemplary plasma-based approach generally includes a two-step process that generally includes exposing a metal such a copper to chlorine and hydrogen plasmas at low temperature (below 20° C.). This process generates a volatile etch product that minimizes surface contamination. In another example, cyclic exposure to an oxidant and hexafluoroacetylacetone (Hhfac) at an elevated temperature such as at 275° C. can be used to selectively etch a metal such as copper. An exemplary electrochemical approach also can include two steps. A first step includes surface-limited sulfidization of the metal such as copper to form a metal sulfide, e.g., Cu₂S, followed by selective wet etching of the metal sulfide, e.g., etching of Cu₂S in HCl. Atomic layer etching is relatively recent technology and optimization for a specific metal is well within the skill of those in the art. The reactions at the surface provide high selectivity and minimal or no attack of exposed dielectric surfaces.

Semiconductor lithography is the formation of three-dimensional relief images or patterns on the semiconductor substrate for subsequent transfer of the pattern to the substrate. In semiconductor lithography, the patterns are formed by a light sensitive polymer called a photoresist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

The photoresist can be formed using conventional deposition techniques such chemical vapor deposition, plasma vapor deposition, sputtering, dip coating, spin-on coating, brushing, spraying and other like deposition techniques can be employed. Following formation of the photoresist, the photoresist is exposed to a desired pattern of radiation such as X-ray radiation, extreme ultraviolet (EUV) radiation, electron beam radiation or the like. Next, the exposed photoresist is developed utilizing a conventional resist development process.

After the development step, the etching step can be performed to transfer the pattern from the patterned photoresist into the interlayer dielectric. The etching step used in forming the at least one opening can include a dry etching process (including, for example, reactive ion etching, ion beam etching, plasma etching or laser ablation), a wet chemical etching process or any combination thereof.

For the sake of brevity, conventional techniques related to making and using aspects of the invention may or may not be described in detail herein. In particular, various aspects of computing systems and specific computer programs to implement the various technical features described herein are well known. Accordingly, in the interest of brevity, many conventional implementation details are only mentioned briefly herein or are omitted entirely without providing the well-known system and/or process details.

In some embodiments, various functions or acts can take place at a given location and/or in connection with the operation of one or more apparatuses or systems. In some embodiments, a portion of a given function or act can be performed at a first device or location, and the remainder of the function or act can be performed at one or more additional devices or locations.

The terminology used herein is for the purpose of describing particular embodiments only and is not intended to be limiting. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, element components, and/or groups thereof.

The corresponding structures, materials, acts, and equivalents of all means or step plus function elements in the claims below are intended to include any structure, material, or act for performing the function in combination with other claimed elements as specifically claimed. The present disclosure has been presented for purposes of illustration and description but is not intended to be exhaustive or limited to the form disclosed. Many modifications and variations will be apparent to those of ordinary skill in the art without departing from the scope and spirit of the disclosure. The embodiments were chosen and described in order to best explain the principles of the disclosure and the practical application, and to enable others of ordinary skill in the art to understand the disclosure for various embodiments with various modifications as are suited to the particular use contemplated.

The diagrams depicted herein are illustrative. There can be many variations to the diagram or the steps (or operations) described therein without departing from the spirit of the disclosure. For instance, the actions can be performed in a differing order or actions can be added, deleted or modified. Also, the term “coupled” describes having a signal path between two elements and does not imply a direct connection between the elements with no intervening elements/connections therebetween. All of these variations are considered a part of the present disclosure.

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” are understood to include any integer number greater than or equal to one, i.e., one, two, three, four, etc. The terms “a plurality” are understood to include any integer number greater than or equal to two, i.e., two, three, four, five, etc. The term “connection” can include both an indirect “connection” and a direct “connection.”

The terms “about,” “substantially,” “approximately,” and variations thereof, are intended to include the degree of error associated with measurement of the particular quantity based upon the equipment available at the time of filing the application. For example, “about” can include a range of ±8% or 5%, or 2% of a given value.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

What is claimed is:

1. A semiconductor structure comprising:
first stacked transistors comprising a first upper transistor over a first lower transistor; and
second stacked transistors adjacent to the first stacked transistors, a gate structure comprising a gate extension into a shallow trench isolation region, wherein a non-conductive frontside gate cut through the gate structure isolates the first stacked transistors and the second stacked transistors, wherein a contact through the non-conductive frontside gate cut contacts the gate extension and is coupled to the first lower transistor.

2. The semiconductor structure of claim 1, wherein the non-conductive frontside gate cut isolates the gate structure into an upper gate structure and a lower gate structure, the lower gate structure including the gate extension.

3. The semiconductor structure of claim 1, wherein the first upper transistor comprises an upper gate structure and the first lower transistor comprises a lower gate structure, the upper and lower gate structures being formed by the non-conductive frontside gate cut.

4. The semiconductor structure of claim 1, wherein the first stacked transistors comprise a middle dielectric isolation layer separating the first upper transistor from the first lower transistor.

5. The semiconductor structure of claim 4, wherein a non-conductive backside gate cut is in contact with the middle dielectric isolation layer, thereby forming a lower gate structure of the first lower transistor.

6. The semiconductor structure of claim 4, wherein a shallow non-conductive frontside gate cut is in contact with both the middle dielectric isolation layer and the non-conductive frontside gate cut.

7. The semiconductor structure of claim 1, wherein a via is connected to the contact in order to couple the gate extension to a frontside interconnect.

8. The semiconductor structure of claim 1, wherein a cavity in the shallow trench isolation region is filled with the gate extension.

9. The semiconductor structure of claim 1, wherein the first stacked transistors comprise a bottom dielectric isolation layer such that the gate extension extends below the bottom dielectric isolation layer.

10. A method comprising:
providing first stacked transistors comprising a first upper transistor over a first lower transistor; and
providing second stacked transistors adjacent to the first stacked transistors, a gate structure comprising a gate extension into a shallow trench isolation region, wherein a non-conductive frontside gate cut through the gate structure isolates the first stacked transistors and the second stacked transistors, wherein a contact through the non-conductive frontside gate cut contacts the gate extension and is coupled to the first lower transistor.

11. The method of claim 10, wherein the non-conductive frontside gate cut isolates the gate structure into an upper gate structure and a lower gate structure, the lower gate structure including the gate extension.

12. The method of claim 10, wherein the first upper transistor comprises an upper gate structure and the first lower transistor comprises a lower gate structure, the upper and lower gate structures being formed by the non-conductive frontside gate cut.

13. The method of claim 10, wherein the first stacked transistors comprise a middle dielectric isolation layer separating the first upper transistor from the first lower transistor.

14. The method of claim 13, wherein a non-conductive backside gate cut is in contact with the middle dielectric isolation layer, thereby forming a lower gate structure of the first lower transistor.

15. The method of claim 13, wherein a shallow non-conductive frontside gate cut is in contact with both the middle dielectric isolation layer and the non-conductive frontside gate cut.

16. The method of claim 10, wherein a via is connected to the contact in order to couple the gate extension to a frontside interconnect.

17. The method of claim 10, wherein a cavity in the shallow trench isolation region is filled with the gate extension.

18. The method of claim 10, wherein the first stacked transistors comprise a bottom dielectric isolation layer such that the gate extension extends below the bottom dielectric isolation layer.

19. A semiconductor structure comprising:
first stacked transistors comprising a first upper transistor over a first lower transistor;
second stacked transistors adjacent to the first stacked transistors on a first side, a gate structure comprising a gate extension into a shallow trench isolation region, wherein a non-conductive frontside gate cut through the gate structure isolates the first stacked transistors and the second stacked transistors, wherein a contact through the non-conductive frontside gate cut contacts the gate extension and is coupled to the first lower transistor;
a first shallow non-conductive frontside gate cut contacts the non-conductive frontside gate cut on the first side of the first stacked transistors; and
a second shallow non-conductive frontside gate cut contacts a non-conductive backside gate cut on a second side of the first stacked transistors, the second side being opposite the first side.

20. The semiconductor structure of claim 19, wherein third stacked transistors are positioned on the second side of the first stacked transistors.
